(19) United States
(12) Patent Application Publication
(10) Pub. No.: US 2025/0275181 A1
(43) Pub. Date: Aug. 28, 2025

(54) ISOLATED BACKSIDE CONTACT AND PLACEHOLDER

(71) Applicant: INTERNATIONAL BUSINESS MACHINES CORPORATION, ARMONK, NY (US)

(72) Inventors: Huimei Zhou, Albany, NY (US); Ruilong Xie, Niskayuna, NY (US); Chen Zhang, Santa Clara, CA (US); Miaomiao Wang, Albany, NY (US)

(21) Appl. No.: 18/586,485

(22) Filed: Feb. 25, 2024

(51) Int. Cl. H01L 29/417; H01L 23/528; H01L 29/06; H01L 29/40; H01L 29/423; H01L 29/66; H01L 29/775

(52) U.S. Cl. CPC H10D 30/6729; H01L 23/5286; H10D 30/014; H10D 30/43; H10D 30/6735; H10D 62/121; H10D 64/01

(57) ABSTRACT

A semiconductor device includes a plurality of gate separated by an interlayer dielectric (ILD), a backside contact. The backside contact is extended below the plurality of gates and a dielectric layer, and from a first gate to a second gate of the plurality of gates, and a placeholder. The placeholder is extended below the plurality of gates and between the second gate and a third gate of the plurality of gates. The backside contact and the placeholder are not directly electrically connected.

### BACKGROUND

### Technical Field

The present disclosure generally relates to semiconductors, and more particularly, to semiconductors with isolated backside contact and placeholder structure, and methods of creation thereof.

### Description of Related Art

Reliability qualification in transistors refers to the testing and verification procedures conducted to assess robustness and demonstrate a transistor's ability to operate stably over its expected lifetime within system specifications. As transistors scale to tiny geometries susceptible to defects and failure mechanisms, rigorous reliability assessment ensures product quality. Some common reliability tests measure transistor parameters after stressing devices under elevated voltages, currents, temperatures or cycling to uncover early life defects and quantify gradual degradation. Statistics from a sample population undergoing such stresses quantify failure rates for liability projections. Other structural analyses probe material wear-out mechanisms affecting transistor terminals, interconnects and dielectrics over aged durations. Various other reliability qualification techniques applied through design, fabrication and operation stages instill confidence that transistors will function per performance targets for warranty periods spanning years, facilitating quality systems relying on integrated circuits.

### SUMMARY

According to an embodiment, a semiconductor device includes a plurality of gates separated by an interlayer dielectric (ILD), a backside contact. The backside contact is extended below the plurality of gates and a dielectric layer, and from a first gate to a second gate of the plurality of gates, and a placeholder. The placeholder is extended below the plurality of gates and between the second gate and a third gate of the plurality of gates. The backside contact and the placeholder are not directly electrically connected.

In some embodiments, the semiconductor device includes a backside interlayer dielectric (BILD) below the plurality of gates, and a shallow trench isolation (STI) within the BILD and over the backside contact.

In some embodiments, the STI isolates the backside contact form direct contact with a gate and the ILD, and the BILD isolates the placeholder and the backside contact from directly connecting to each other.

In some embodiments, the STI is made of at least one of silicon dioxide and silicon nitride. The dielectric layer is made of silicon dioxide.

In some embodiments, the semiconductor device includes a first source/drain region above the placeholder.

In some embodiments, the semiconductor device includes a source/drain contact above the first source/drain region electrically connecting the source/drain region to a back end of line (BEOL) on a frontside of the semiconductor device.

In some embodiments, the semiconductor device includes a plurality of nanosheets extended horizontally along each of the plurality of gates.

According to an embodiment, a semiconductor device includes a first active layer having a first width, a second active layer adjacent to the first active layer, the second active layer having a second width, a backside power delivery network, and a fin cut region in the second active layer. The first width is larger than the second width.

In some embodiments, the first width has a first end and a second end, and the second width has a third end and a fourth end, and the first end and the third end are coplanar.

In some embodiments, the semiconductor device includes a first backside contact on the second end of the first active layer, and a second backside contact on the third end of the second active layer.

In some embodiments, the semiconductor device includes a plurality of gates separated by an interlayer dielectric (ILD), a backside interlayer dielectric (BILD) below the plurality of gates, a dielectric layer within the BILD and above the second backside contact, and a shallow trench isolation (STI) within the BILD. The BILD isolates the placeholder and the second backside contact from a direct electrical connection.

In some embodiments, the STI is made of silicon nitride and wherein the dielectric layer is made of silicon dioxide.

In some embodiments, the semiconductor device includes a first source/drain region above the placeholder.

In some embodiments, the semiconductor device includes a plurality of nanosheets extended horizontally along each of the plurality of gates.

According to an embodiment, a method for fabricating a semiconductor device includes forming a plurality of gates, isolating the plurality of gates by an interlayer dielectric (ILD), forming a backside contact extended below the plurality of gates and from a first gate to a second gate of the plurality of gates, forming a placeholder extended below the plurality of gates and between the second gate and a third gate of the plurality of gates, and isolating the backside contact and the placeholder from a direct electrical connection by a backside interlayer dielectric (BILD).

In some embodiments, the method includes forming a shallow trench isolation (STI) within the BILD and over the backside contact.

In some embodiments, the method includes isolating the backside contact form direct contact with a gate and the ILD by the STI.

In some embodiments, the method includes forming a source/drain region above the placeholder.

In some embodiments, the method includes electrically connecting the source/drain region to a back end of line (BEOL) on a frontside of the semiconductor device via a source/drain contact.

In some embodiments, the method includes forming a plurality of nanosheets extended horizontally along each of the plurality of gates.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a semiconductor device, in accordance with some embodiments.

FIG. 1B depicts the top-view from which the semiconductor device is illustrated.

FIGS. 2A-2B illustrate a semiconductor device, in accordance with some embodiments.

FIG. 2C depicts the top-view from which the semiconductor device of FIGS. 2A-2B is illustrated.

FIGS. 3A-3B illustrate a semiconductor device, in accordance with some embodiments.

FIG. 3C depicts the top-view from which the semiconductor device of FIGS. 3A-3B is illustrated.

FIG. 4 illustrates a semiconductor device after the formation of the frontside contact, in accordance with some embodiments.

FIG. 5 illustrates a semiconductor device after the removal of the silicon substrate, in accordance with some embodiments.

FIG. 6 illustrates a semiconductor device after formation of the backside interlayer dielectric, in accordance with some embodiments.

FIG. 7 illustrates a semiconductor device after patterning of the backside contact, in accordance with some embodiments.

FIG. 8 illustrates a semiconductor device after the removal of the SiGe layer, in accordance with some embodiments.

FIG. 9 illustrates a semiconductor device after the backside contact metallization, in accordance with some embodiments.

FIG. 10 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to reliability qualification in a semiconductor device, i.e., a transistor. Reliability qualification refers to the testing and verification procedures conducted to assess robustness and demonstrate a transistor's ability to operate stably over its expected lifetime within system specifications. As transistors scale to tiny geometries susceptible to defects and failure mechanisms, rigorous reliability assessment ensures product quality.

The typical process flows and transistor architectures used currently are unable to enable evaluation of the integrity and lifetime of the transistors. The placeholder and the backside contact may be too close to each other that can cause shorting over time, which shortens the effective lifetime of the device. The inadequacy of current technology in evaluating the lifetime of the transistor especially stems from the structural constraint that the source/drain and the gate are internally connected at the source/drain terminals, which makes it impossible to test reliability of the backside contact to placeholder independently.

In view of the above considerations, disclosed is a semiconductor device with isolated backside contact and placeholder which enables reliability qualification and verification of the backside contact and placeholder across the semiconductor device's backside power delivery network.

Accordingly, the teachings herein provide methods and systems of semiconductor device formation with isolated backside contact and placeholder. The techniques described herein may be implemented in a number of ways. Example implementations are provided below with reference to the following figures.

Example Semiconductor Device with Isolated Backside Contact and Placeholder Structure

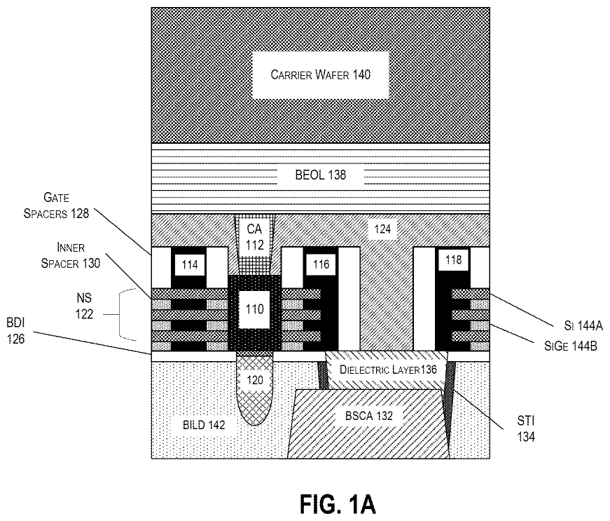

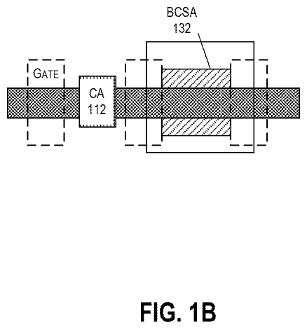

Reference now is made to FIG. 1A, which is a simplified cross-section view of a semiconductor device, consistent with an illustrative embodiment. FIG. 1B illustrates a top-down view of the semiconductor device depicted in FIG. 1A. The disclosed semiconductor device can include a source/drain region 110, a source/drain contact, CA 112, a first gate 114, a second gate 116, a third gate 118, a placeholder 120, a plurality of nanosheets, NS 122, an interlayer dielectric, ILD 124, a dielectric layer, BDI 126, a gate spacer 128, an inner spacer 130, a backside contact, BSCA 132, a shallow trench isolation, STI 134, made of dielectric layer 136, a back end of line, BEOL 138, a carrier wafer 140, and a bottom ILD, BILD 142.

Generally, the source/drain regions, e.g., the source/drain region 110, are salient components that play relevant roles in the semiconductor device's operation. In various embodiments, the source/drain region 110 is a region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The CA 112, located over the source/drain region 110, establishes a connection between the source/drain region 110 and the BEOL 138. The CA 112 ensures efficient electrical routing and connectivity within the semiconductor device. The fabrication of the CA 112 can involve lithography and etching processes to define the contact area. The CA 112 can be made using conductive materials such as copper (Cu) or tungsten (W).

In various embodiments, the first gate 114, the second gate 116, and the third gate 118 serve as control elements that regulate the flow of current through the semiconductor device. The first gate 114, the second gate 116, and the third gate 118 can be composed of a conductive material. The first gate 114, the second gate 116, and the third gate 118 can control the flow of electric current between the source and drain regions.

In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the channel region. In addition to acting as a switch, modulating the gate voltage can enable the first gate 114, the second gate 116, and the third gate 118 to control the current flowing through the channel region, resulting in amplified output signals.

In an embodiment, the first gate 114, the second gate 116, and the third gate 118 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the first gate 114, the second gate 116, and the third gate 118, along with other semiconductor device components, can facilitate the miniaturization and integration of electronic circuits. The ability to control the channel region's conductivity through the gate voltage allows for compact and highly efficient circuit designs.

The placeholder 120 can be epitaxially grown. The use of the placeholder 120 can provide more flexibility in the fabrication process, allowing for the creation of complex geometries or the integration of different types of materials.

The NS 122 can be alternating, vertically-oriented sheets, which can drive current in a small footprint area. In some embodiments, NS 122 includes silicon nanowires. In other words, NS 122 includes three-dimensional structures in the gate, which are extended from a source region towards a drain region.

The ILD 124 can be a layer of insulating material to electrically isolate and provide mechanical support between different layers of conducting and active components. The ILD 124 can enable efficient signal transmission, reduce crosstalk, and ensure the proper functioning of the semiconductor device. In an embodiment, the ILD 124 can electrically isolate adjacent conducting layers or active components in the semiconductor device. By providing insulation between different layers, the ILD 124 can prevent electrical shorts, reduce (e.g., minimize) leakage current, and ensure that signals are directed only along the desired pathways. In some embodiments, the ILD 124 can help reduce parasitic capacitance between adjacent metal interconnects or active devices and provide mechanical support to the semiconductor device's structure.

The BDI 126 can electrically isolate individual components in the semiconductor device, and provide electrical isolation between the components. That is, the BDI 126 can ensure that the operation of one component does not interfere with the operation of the others. By using a dielectric layer, which is an insulating layer that does not conduct electricity, the BDI 126 effectively prevents electrical crosstalk between the transistors and allows each one to operate independently. Further, by electrically isolating each transistor from the other, the BDI 126 can reduce the potential for crosstalk, which is the unwanted transfer of signals between circuit elements, thereby improving the overall performance of the semiconductor device.

By isolating each transistor, BDI 126 helps to prevent the failure of one transistor from affecting the others. This can improve the overall reliability of the device. Additionally, the BDI 126 allows for more flexibility in device design, as it allows each transistor in the stack to be accessed and controlled independently. This can be beneficial in a variety of applications where specific transistors may need to be activated or deactivated based on certain conditions. In some embodiments, the BDI 126 can help decrease the parasitic capacitance associated with the transistor, which can lead to faster switching times and improved performance.

The gate spacer 128 is an insulating material layer that surrounds and isolates the gate electrode of the semiconductor device. The gate spacer 128 electrically isolates the gate from a source/drain region to prevent unwanted electrical leakage. In some embodiments, the gate spacer 128 can help define the length of the gate beneath the gate electrode. In some embodiments, the gate spacer 128 is made of silicon dioxide (SiO2), silicon nitride (Si3N4), or a high-k dielectric.

The inner spacer 130 is an insulating material layer that isolates the nanosheets of the semiconductor device. The inner spacer 130 electrically isolates the individual nanosheets from each other to prevent unwanted electrical leakage. In some embodiments, the gate spacer 128 is made of silicon dioxide (SiO2), silicon nitride (Si3N4), or a high-k dielectric.

The BSCA 132 is a region on the backside of the semiconductor device where electrical connections are made. By establishing the electrical contacts, the BSCA 132 ensures the proper functioning of the semiconductor device and facilitates electrical signal transmission. The BSCA 132 can serve as a thermal interface between the semiconductor device and a heat sink or other cooling mechanisms. By establishing direct contact with the substrate, the BSCA 132 can conduct the heat away from the semiconductor device, and contribute to improved thermal dissipation. In some embodiments, the BSCA 132 can help mitigate parasitic effects, such as substrate coupling or substrate noise, from the semiconductor device. In further embodiments, the BSCA 132 can allow for increased integration density in the semiconductor device. In an embodiment, the BSCA 132 can serve as a means of providing electrostatic discharge (ESD) protection to the semiconductor device. ESD events can cause significant damage to sensitive electronic components and thus should be avoided. The BSCA 132 is located below the dielectric layer 136 with no direct contact with the any of the gates and the placeholder 120.

The dielectric layer 136 is formed below the second gate 116 and the third gate 118. The sidewalls of the dielectric layer 136 can be covered by the STI 134. The BSCA 132 can be located below the dielectric layer 136. In some embodiments, the dielectric layer 136 is made of silicon dioxide (SiO2). In one embodiment, the CA 112 can be used to connect various elements of the semiconductor device to the BEOL 138. The STI 134 helps prevent electrical crosstalk and interference between adjacent components, allowing for the proper functioning of integrated circuits. The BILD 142 can be an insulating material or layer used to isolate and provide electrical insulation between the semiconductor device's active regions and the BSCA 132, and to prevent unwanted electrical contact between the active regions and the backside contact, ensuring the proper functioning and integrity of the semiconductor device. In various embodiments, the BILD 142 can act as a protective layer, shielding the active regions of the semiconductor device from external contaminants, moisture, and mechanical stress. The BILD 142 can further help prevent physical damage, such as scratches or particle contamination, which could adversely affect semiconductor device performance. Additionally, the BILD 142 can act as a barrier against moisture ingress, which can cause corrosion and degradation of the semiconductor device's components.

In several embodiments, the BILD 142 can provide structural support to the semiconductor device by maintaining the mechanical integrity and stability of the semiconductor device. The BILD 142 can further help prevent the warping, bending, or cracking of the substrate, particularly during the manufacturing process or subsequent handling. The BILD 142 can ensure that the semiconductor device remains mechanically robust and maintains its dimensional stability.

In an embodiment, the BILD 142 can also serve as a planarization layer in the semiconductor device fabrication process. As various layers are deposited and patterned on the front side of the semiconductor device, irregularities or topographic variations may arise. The BILD 142 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 142 can contribute to improved overall semiconductor device performance. In several embodiments, BILD 142 can facilitate wafer-level testing of the semiconductor device. By providing electrical isolation between the active regions and the backside contact, individual semiconductor device or elements on the semiconductor device can be electrically accessed and tested without interference from neighboring devices or components. This enables efficient and accurate wafer-level testing, ensuring quality control during semiconductor manufacturing.

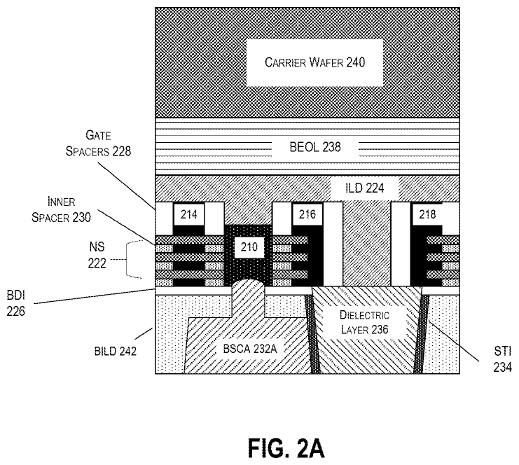

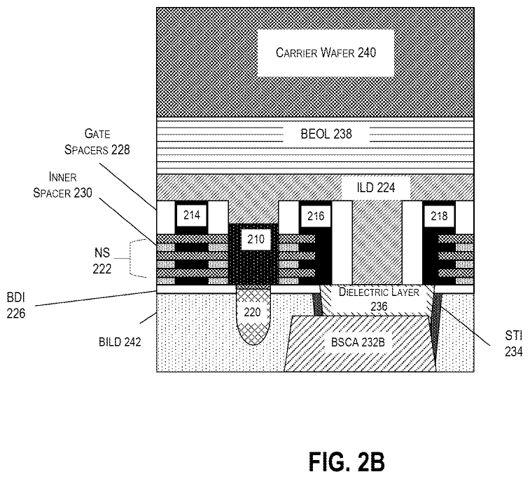

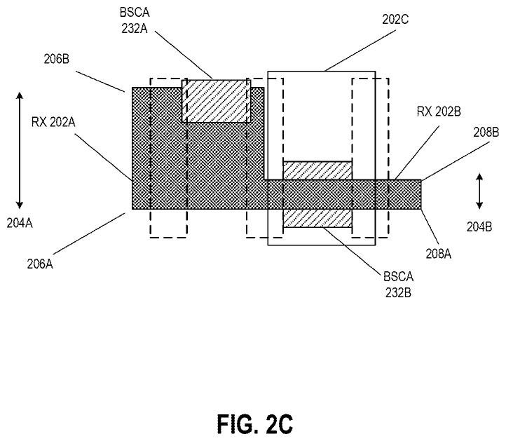

Reference now is made to FIGS. 2A-2B, which are simplified cross-section views of a semiconductor device, consistent with an illustrative embodiment. FIG. 2C illustrates a top-down view of the semiconductor device depicted in FIGS. 2A-2B. As shown in FIG. 2C, the semiconductor device includes a first active layer, RX 202A, and a second active layer, RX 202B, adjacent to the RX 202A. The RX 202A can have a first width 204A, and the RX 202B can have a second width 204B. The first width 204A has a first end 206A and a second end 206B, and the second width 204B has a third end 208A and a fourth end 208B. The first end 206A and the third end 208A can be coplanar. The first width 204A is larger than the second width 204B.

The semiconductor device can further include a fin cut region, FC 202C, in the RX 202B, which extends between two gates. The RX 202A can include a source/drain region 210, a placeholder 220, and a first backside contact, BSCA 232A. The BSCA 232A can intrude into the BDI 226 and establish a direct electrical connection to the source/drain region 210. The RX 202B can include a dielectric layer 236 and a second backside contact, BSCA 232B. The BSCA 232B, which is located below the dielectric layer 236, has no direct electrical contact with a gate and the placeholder 220. The semiconductor device can further include the first gate 214, the second gate 216, a third gate 218, a plurality of nanosheets, NS 222, an ILD 224, a BDI 226, a gate spacer 228, an inner spacer 230, a STI 234, a BEOL 238, a carrier wafer 240, and a BILD 242. In some embodiments, the BSCA 232A is located on the second end 206B of the RX 202A, and the BSCA 232B is located on the third end 208A of the RX 202B. Thus, the BSCA 232A and the BSCA 232B form a diagonal formation.

The first gate 214, the second gate 216, and the third gate 218, are separated by the ILD 224. The BILD 242 which is located below the gate, e.g., the first gate 214, the second gate 216, and the third gate 218, can isolate the placeholder 220 and the BSCA 232B from a direct electrical connection.

In various embodiments, the source/drain region 210, located above the placeholder 220, is a region within the semiconductor material, e.g., the semiconductor device, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied. The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In various embodiments, the first gate 214, the second gate 216, and the third gate 218 serve as control elements that regulate the flow of current through the semiconductor device. The first gate 214, the second gate 216, and the third gate 218 can be composed of a conductive material. The first gate 214, the second gate 216, and the third gate 218 can control the flow of electric current between the source and drain regions. In addition to acting as a switch, modulating the gate voltage can enable the first gate 214, the second gate 216, and the third gate 218 to control the current flowing through the channel region, resulting in amplified output signals.

In an embodiment, the first gate 214, the second gate 216, and the third gate 218 can enable the implementation of Boolean logic operations, such as AND, OR, and NOT, by controlling the flow of current based on the input voltages. In some embodiments, the first gate 214, the second gate 216, and the third gate 218, along with other semiconductor device components, can facilitate the miniaturization and integration of electronic circuits. The ability to control the channel region's conductivity through the gate voltage allows for compact and highly efficient circuit designs.

The placeholder 220 can be epitaxially grown. The use of the placeholder 220 can provide more flexibility in the fabrication process, allowing for the creation of complex geometries or the integration of different types of materials.

The NS 222 can be alternating, vertically-oriented sheets, which can drive current in a small footprint area. In some embodiments, NS 222 includes silicon nanowires. In other words, NS 222 includes three-dimensional structures in the gate, which are extended from a source region towards a drain region.

The ILD 224 can be a layer of insulating material to electrically isolate and provide mechanical support between different layers of conducting and active components. The ILD 224 can enable efficient signal transmission, reduce crosstalk, and ensure the proper functioning of the semiconductor device. In an embodiment, the ILD 224 can electrically isolate adjacent conducting layers or active components in the semiconductor device. By providing insulation between different layers, the ILD 224 can prevent electrical shorts, reduce (e.g., minimize) leakage current, and ensure that signals are directed only along the desired pathways. In some embodiments, the ILD 224 can help reduce parasitic capacitance between adjacent metal interconnects or active devices and provide mechanical support to the semiconductor device's structure.

The BDI 226 can electrically isolate individual components in the semiconductor device, and provide electrical isolation between the components. That is, the BDI 226 can ensure that the operation of one component does not interfere with the operation of the others. By using a dielectric layer, which is an insulating layer that does not conduct electricity, the BDI 226 effectively prevents electrical crosstalk between the transistors and allows each one to operate independently. Further, by electrically isolating each transistor from the other, the BDI 226 can reduce the potential for crosstalk, which is the unwanted transfer of signals between circuit elements, thereby improving the overall performance of the semiconductor device.

By isolating each transistor, BDI 226 helps to prevent the failure of one transistor from affecting the others. This can improve the overall reliability of the device. Additionally, the BDI 226 allows for more flexibility in device design, as it allows each transistor in the stack to be accessed and controlled independently. This can be beneficial in a variety of applications where specific transistors may need to be activated or deactivated based on certain conditions. In some embodiments, the BDI 226 can help decrease the parasitic capacitance associated with the transistor, which can lead to faster switching times and improved performance.

The gate spacer 228 is an insulating material layer that surrounds and isolates the gate electrode of the semiconductor device. The gate spacer 228 electrically isolates the gate from a source/drain region to prevent unwanted electrical leakage. In some embodiments, the gate spacer 228 can help define the length of the gate beneath the gate electrode. In some embodiments, the gate spacer 228 is made of silicon dioxide (SiO2), silicon nitride (Si3N4), or a high-k dielectric.

The inner spacer 230 is an insulating material layer that isolates the nanosheets of the semiconductor device. The inner spacer 230 electrically isolates the individual nanosheets from each other to prevent unwanted electrical leakage. In some embodiments, the gate spacer 228 is made of silicon dioxide (SiO2), silicon nitride (Si3N4), or a high-k dielectric.

The BSCA 232A and the BSCA 232B are regions on the backside of the semiconductor device where electrical connections are made. By establishing the electrical contacts, the BSCA 232A and BSCA 232B ensure the proper functioning of the semiconductor device and facilitates electrical signal transmission. The BSCA 232A and BSCA 232B can serve as a thermal interface between the semiconductor device and a heat sink or other cooling mechanisms. By establishing direct contact with the substrate, the BSCA 232A and BSCA 232B can conduct the heat away from the semiconductor device, and contribute to improved thermal dissipation. In some embodiments, the BSCA 232A and BSCA 232B can help mitigate parasitic effects, such as substrate coupling or substrate noise, from the semiconductor device. In further embodiments, the BSCA 232A and BSCA 232B can allow for increased integration density in the semiconductor device. In an embodiment, the BSCA 232A and BSCA 232B can serve as a means of providing electrostatic discharge (ESD) protection to the semiconductor device. ESD events can cause significant damage to sensitive electronic components and thus should be avoided.

The dielectric layer 236 is formed below the second gate 216 and the third gate 218. The sidewalls of the dielectric layer 236 can be covered by the STI 234. The BSCA 232B can be located below the dielectric layer 236. In some embodiments, the dielectric layer 236 is made of silicon dioxide (SiO2). The STI 234 helps prevent electrical crosstalk and interference between adjacent components, allowing for the proper functioning of integrated circuits. The BILD 242 can be an insulating material or layer used to isolate and provide electrical insulation between the semiconductor device's active regions and the BSCA 232A and BSCA 232B, and to prevent unwanted electrical contact between the active regions and the backside contact, ensuring the proper functioning and integrity of the semiconductor device. In various embodiments, the BILD 242 can act as a protective layer, shielding the active regions of the semiconductor device from external contaminants, moisture, and mechanical stress. The BILD 242 can further help prevent physical damage, such as scratches or particle contamination, which could adversely affect semiconductor device performance. Additionally, the BILD 242 can act as a barrier against moisture ingress, which can cause corrosion and degradation of the semiconductor device's components.

In several embodiments, the BILD 242 can provide structural support to the semiconductor device by maintaining the mechanical integrity and stability of the semiconductor device. The BILD 242 can further help prevent the warping, bending, or cracking of the substrate, particularly during the manufacturing process or subsequent handling. The BILD 242 can ensure that the semiconductor device remains mechanically robust and maintains its dimensional stability.

In an embodiment, the BILD 242 can also serve as a planarization layer in the semiconductor device fabrication process. As various layers are deposited and patterned on the front side of the semiconductor device, irregularities or topographic variations may arise. The BILD 242 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 242 can contribute to improved overall semiconductor device performance. In several embodiments, BILD 242 can facilitate wafer-level testing of the semiconductor device. By providing electrical isolation between the active regions and the backside contact, individual semiconductor device or elements on the semiconductor device can be electrically accessed and tested without interference from neighboring devices or components. This enables efficient and accurate wafer-level testing, ensuring quality control during semiconductor manufacturing.

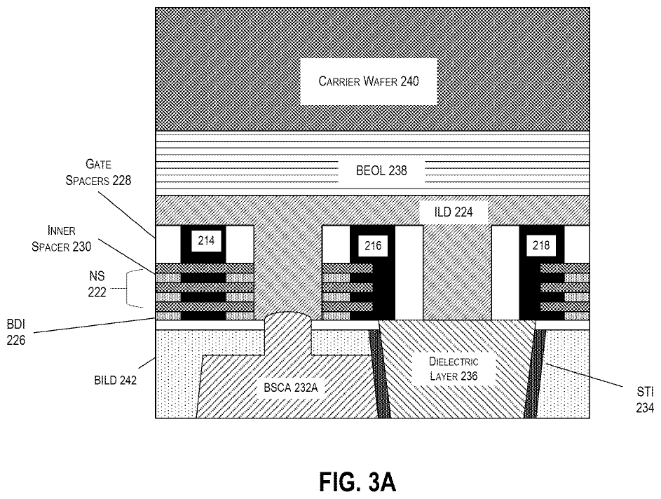

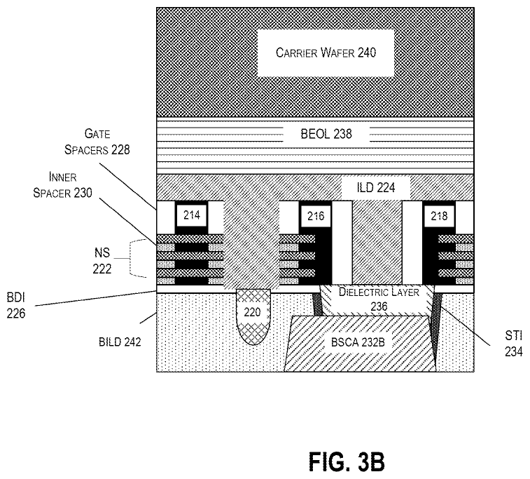

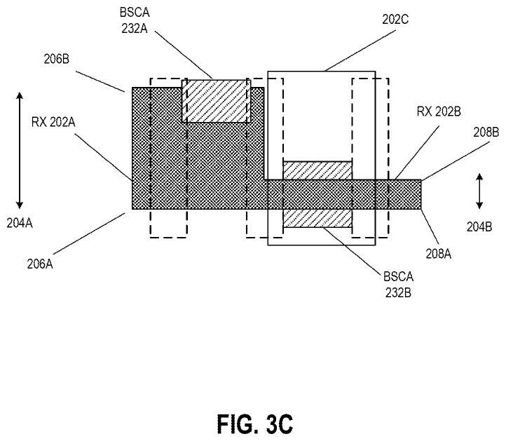

FIGS. 3A-3B illustrate simplified cross-section views of a semiconductor device, consistent with an illustrative embodiment. FIG. 3C illustrates a top-down view of the semiconductor device depicted in FIGS. 3A-3B. However, while the semiconductor device depicted in FIGS. 3A-3B can be substantially similar to the semiconductor device depicted in FIGS. 2A-2B, there is no source/drain region in the semiconductor device shown in FIGS. 3A-3B.

Example Fabrication of Semiconductor Device with Isolated Backside Contact and Placeholder

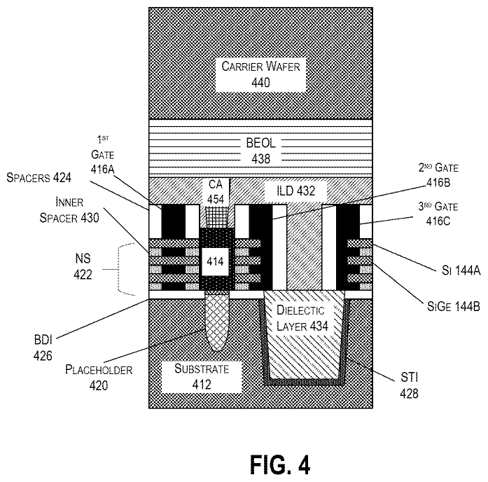

With the foregoing description of an example semiconductor device, it may be helpful to discuss an example process of manufacturing the same. To that end, FIGS. 4-9 illustrate various acts in the manufacture of a semiconductor device, consistent with illustrative embodiments.

Reference now is made to FIG. 4, which is a simplified cross-section view of a semiconductor device, after formation of the source/drain regions, consistent with an illustrative embodiment. Once the source/drain region is formed, the semiconductor device can include a substrate 412, a source/drain region 414, a source/drain contact, CA 454, a first gate 416A, a second gate 416B, a third gate 416C, a placeholder 420, nanosheets channels, NS 422, spacers 424, inner spacer 430, STI 428, an interlayer dielectric, ILD 432, a dielectric layer 434, a bottom dielectric layer, BDI 426, a back end of line, BEOL 438, and a carrier wafer 440.

In the illustrative example depicted in FIG. 4, the semiconductor device is depicted as being on silicon as the substrate 412, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 412 may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In some embodiments, the NS 422 can be formed by alternating layers of Si layers 444A and SiGe layers 444B, in which sidewalls of the SiGe layers are indented and covered by the inner spacer 430 The SiGe layers can subsequently be removed and replaced with gate region materials.

The spacers 424 can be thin insulating layers or materials placed on the sidewalls of the gate regions. The spacers 424 can help control the effective channel length of the semiconductor device. In an embodiment, the spacers 424 can allow for control over the channel's conductive properties, including resistance and carrier mobility, which can contribute to improved performance of the semiconductor device. The spacers 424 can be a low-k material.

In some embodiments, the spacers 24 can act as insulating layers between the gate regions and the source/drain region 414. That is, the spacers 424 can help prevent current leakage or short circuits between the gate regions and the source/drain region 414. Such isolation can help maintain the integrity of the semiconductor device's electrical operation and prevent unintended current flow that could negatively impact the performance of the semiconductor device and reliability.

In further embodiments, the spacers 424 can be utilized to modulate the overlapping capacitance between the gate regions and the source/drain region 414. Overlapping capacitance can affect the semiconductor device's electrical characteristics, such as threshold voltage and switching behavior. Thus, by adjusting the thickness and material properties of the spacers 424 the overlapping capacitance can be optimized, which can allow for better control and modulation of the semiconductor device's behavior. In several embodiments, the spacers 424 can help mitigate the short-channel effects by physically separating the gate regions from the source/drain region 414. To that end, the spacers 424 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability.

In an embodiment, the spacers 424 can serve as barriers that prevent the lateral diffusion of dopant atoms from the source/drain region 414, into the channel region during the doping process. Such diffusion can alter the channel characteristics and compromise the semiconductor device's performance. By confining the dopant diffusion, the spacers 424 can contribute to maintaining the desired semiconductor device's characteristics and electrical behavior. In some embodiments, the spacers 424 can be formed over the sidewalls of the gate regions. The spacers 424 can be formed by deposition techniques. Alternatively, the spacers 424 can be formed by etching or selectively epitaxially growing the spacers 424 over the sidewalls of the gate regions. In various embodiments, the spacers 424 can include SiGe.

In an embodiment, the inner spacer 424, similar to the spacers 424, can act as insulating layers between the gate regions and the source/drain region 414. In various embodiments, the inner spacer 424 can be the same as the spacers 424, which are formed over portions of the gate regions confined between the nanosheet gates, NS 422.

The CA 454 can be formed over the source/drain region 414 connecting the source/drain region 414 to the BEOL 448. The placeholder 420 can be made of SiGe. In some embodiments, one or more the STI 428, the spacers 424, and the inner spacer 424 can be made of SiN. One or more of the ILD 432 and the dielectric layer 434 can be made of SiO2.

In some embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

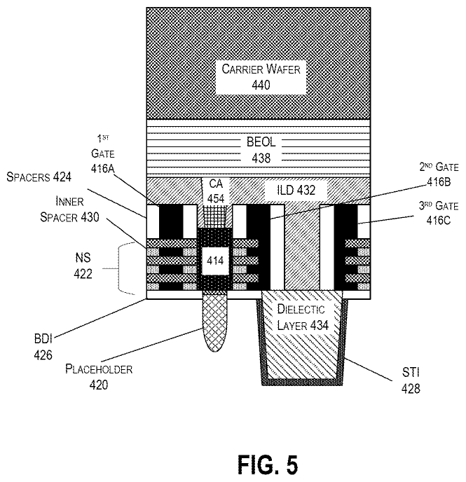

FIG. 5 illustrates a semiconductor device after the removal of the substrate, in accordance with some embodiments. Once the substrate is removed, the placeholder 420, the STI 428 and the BDI 426 are exposed.

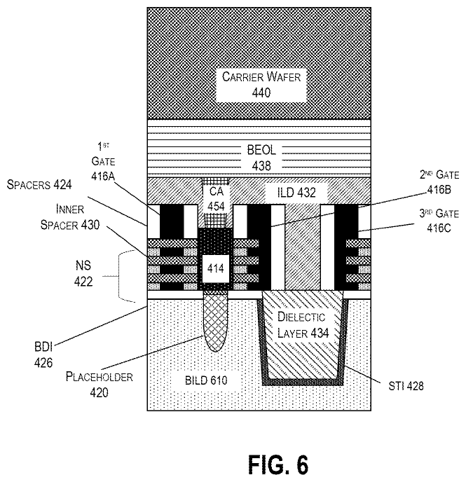

FIG. 6 illustrates a semiconductor device after the formation of the backside interlayer dielectric, in accordance with some embodiments. In some embodiments, the backside interlayer dielectric, BILD 610, is formed over the placeholder 420, the STI 428 and the BDI 426. The BILD 410 can be made of SiO2. In some embodiments, a planarization process can be performed. In an embodiment, a chemical-mechanical polishing (CMP) process is further processed after the formation of the BILD 610. The BILD 610 can be an insulating material or layer used to isolate and provide electrical insulation between the semiconductor device's active regions and to prevent unwanted electrical contact between the active regions and the backside contact, ensuring the proper functioning and integrity of the semiconductor device. In various embodiments, the BILD 610 can act as a protective layer, shielding the active regions of the semiconductor device from external contaminants, moisture, and mechanical stress. The BILD 610 can further help prevent physical damage, such as scratches or particle contamination, which could adversely affect semiconductor device performance. Additionally, the BILD 610 can act as a barrier against moisture ingress, which can cause corrosion and degradation of the semiconductor device's components.

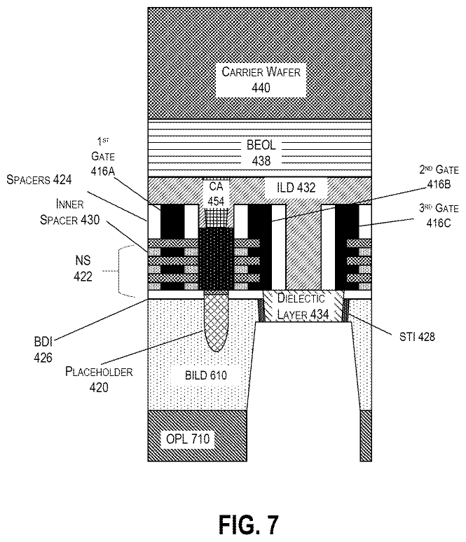

FIG. 7 illustrates a semiconductor device after the patterning of the backside contact, in accordance with some embodiments. In some embodiments, an organic planarization layer, OPL 710 is formed over the semiconductor device. The OPL 710 can include a photo-sensitive organic polymer having a light-sensitive material that, when exposed to electromagnetic (EM) radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). In some embodiments, the OPL 710 can include any organic polymer and a photoactive compound having a molecular structure that can attach to the molecular structure of the organic polymer. In some embodiments, the OPL 710 material is selected to be compatible with an overlying antireflective coating (not shown) and/or an overlying photoresist (not shown). In some embodiments, the OPL 710 can be applied using spin coating technology, although other techniques are within the contemplated scope of the present disclosure. The backside contact patterning is performed by removing portions of the OPL 710, the BILD 610, the STI 428, and the dielectric layer 434.

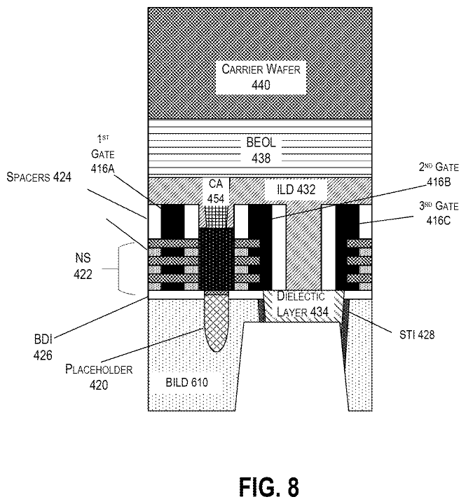

FIG. 8 illustrates a semiconductor device after the removal of organic planarization layer, in accordance with some embodiments. In some embodiments, the OPL is removed to create a flat surface for subsequent lithography and deposition steps.

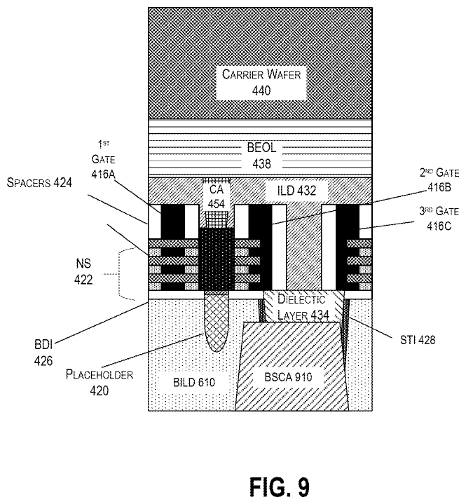

FIG. 9 illustrates a semiconductor device after the formation of the backside contact metallization, in accordance with some embodiments. In some embodiments, the backside contact, BSCA 910, is formed below the dielectric layer 434 and the STI 428 liner, and within the BILD 610 by filling by a metal contact. A backside power delivery network, BSPDN (not shown), can be formed below the BILD 610 and the BSCA 910. The BSPDN can include conductive metal layers and architecture that distribute power supply voltage and ground lines across the integrated circuit. The backside power grid can complement supply routing on the frontside metal stack. Backside power distribution lines can use thick copper fill between the semiconductor device and package bumps/pillars.

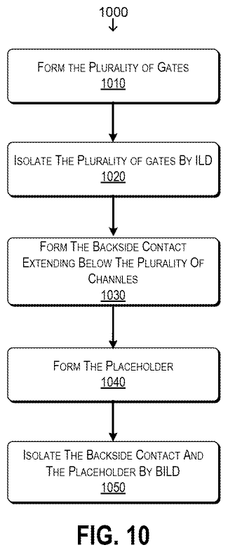

FIG. 10 illustrate a block diagram of a method 1000 for forming the semiconductor device, in accordance with some embodiments. As shown by block 1010, the plurality of gates is formed.

As shown by block 1020, the placeholder is formed. The placeholder can be extended below the plurality of gates and between the second gate and the third gate of the plurality of gates before source/drain region is formed.

As shown by block 1030, the plurality of gates is isolated by an interlayer dielectric (ILD).

As shown by block 1040, the backside contact is formed extending below the plurality of gates. The backside contact can be extended from a first gate to a second gate of the plurality of gates.

As shown by block 1050, the backside contact and the placeholder are isolated from a direct electrical connection by a backside interlayer dielectric (BILD).

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a plurality of gates separated by an interlayer dielectric (ILD);
a backside contact, wherein:
the backside contact is extended below the plurality of gates and a dielectric layer; and
the backside contact is extended from a first gate to a second gate of the plurality of gates; and
a placeholder, wherein:
the placeholder is extended below the plurality of gates, and between the second gate and a third gate of the plurality of gates; and
the backside contact and the placeholder are not directly electrically connected.

2. The semiconductor device of claim 1, further comprising:
a backside interlayer dielectric (BILD) below the plurality of gates; and
a shallow trench isolation (STI) within the BILD and over the backside contact.

3. The semiconductor device of claim 2, wherein the STI isolates the backside contact from direct contact with a gate and the ILD, and wherein the BILD isolates the placeholder and the backside contact from directly connecting to each other.

4. The semiconductor device of claim 3, wherein:
the STI is made of at least one of silicon dioxide and silicon nitride; and
the dielectric layer is made of silicon dioxide.

5. The semiconductor device of claim 1, further comprising a source/drain region above the placeholder.

6. The semiconductor device of claim 5, further comprising: a source/drain contact above the source/drain region electrically connecting the source/drain region to a back end of line (BEOL) on a frontside of the semiconductor device.

7. The semiconductor device of claim 1, further comprising a plurality of nanosheets extended horizontally along each of the plurality of gates.

8. A semiconductor device, comprising:
a first active layer having a first width;
a second active layer adjacent to the first active layer, the second active layer having a second width;
a backside contact below a plurality of gates and a dielectric layer; and
a placeholder,
wherein the first width is larger than the second width.

9. The semiconductor device of claim 8, wherein:
the first width has a first end and a second end;
the second width has a third end and a fourth end; and
the first end and the third end are coplanar.

10. The semiconductor device of claim 9, further comprising:
a first backside contact on the second end of the first active layer; and
a second backside contact on the third end of the second active layer.

11. The semiconductor device of claim 10, further comprising:
a plurality of gates separated by an interlayer dielectric (ILD);
a backside interlayer dielectric (BILD) below the plurality of gates;
a dielectric layer within the BILD and above the second backside contact; and
a shallow trench isolation (STI) within the BILD, wherein the BILD isolates a placeholder and the second backside contact from a direct electrical connection.

12. The semiconductor device of claim 11, wherein:
the STI is made of silicon nitride; and
the dielectric layer is made of silicon dioxide.

13. The semiconductor device of claim 8, further comprising a first source/drain region above a placeholder.

14. The semiconductor device of claim 7, further comprising a plurality of nanosheets extended horizontally along each of the plurality of gates.

15. A method for fabrication of a semiconductor device, the method comprising:
forming a plurality of gates;
isolating the plurality of gates by an interlayer dielectric (ILD);
forming a backside contact extended below the plurality of gate and from a first gate to a second gate of the plurality of gates;
forming a placeholder extended below the plurality of gate and between the second gate and a third gate of the plurality of gates; and
isolating the backside contact and the placeholder from a direct electrical connection by a backside interlayer dielectric (BILD).

16. The method of claim 15, further comprising forming a shallow trench isolation (STI) within the BILD and over the backside contact.

17. The method of claim 16, further comprising isolating the backside contact from direct contact with a gate of the plurality of gates and the ILD by the STI.

18. The method of claim 15, further comprising forming a source/drain region above the placeholder.

19. The method of claim 18, further comprising electrically connecting the source/drain region to a back end of line (BEOL) on a frontside of the semiconductor device via a source/drain contact.

20. The method of claim 15, further comprising forming a plurality of nanosheets extended horizontally along each of the plurality of gates.
